(19) United States
(12) Patent Application Publication
(10) Pub. No.: US 2024/0387787 A1
(43) Pub. Date: Nov. 21, 2024

(54) DISPLAY APPARATUS

(71) Applicant: AUO Corporation, Hsinchu (TW)

(72) Inventors: Cheng-He Ruan, Hsinchu (TW); Jian-Jhou Tseng, Hsinchu (TW); Chih-Yuan Hou, Hsinchu (TW)

(73) Assignee: AUO Corporation, Hsinchu (TW)

(21) Appl. No.: 18/523,928

(22) Filed: Nov. 30, 2023

(30) Foreign Application Priority Data
May 15, 2023 (TW) 112117879

(51) Int. Cl. H01L 33/62; H01L 25/16

(52) U.S. Cl. CPC H01L 33/62; H01L 25/167

(57) ABSTRACT

A display apparatus includes a light-transmitting substrate, a pad group, a mini-IC, a first wire, and a first light-emitting element. The pad group includes a first pad, a second pad, and a third pad. The mini-IC is bonded to the pad group. The first wire is electrically connected to the first pad. The first pad and the second pad have first sides and second sides opposite to each other. The third pad is located on the first sides of the first pad and the second pad. The first wire is structurally separated from the second pad and the third pad. A winding segment of the first wire is disposed between the second pad and the third pad and bypasses the second pad from the first sides of the first pad and the second pad so as to extend toward the second sides of the first pad and the second pad.

### CROSS-REFERENCE TO RELATED APPLICATION

This application claims the priority benefit of Taiwan application serial no. 112117879, filed on May 15, 2023. The entirety of the above-mentioned patent application is hereby incorporated by reference herein and made a part of this specification.

### BACKGROUND

### Technical Field

The disclosure relates to an optoelectronic device, and particularly relates to a display apparatus.

### Description of Related Art

Transparent display panels can be used in a variety of fields, such as smart window screens in home entrances, smart display windows in retail areas, etc. Taking a light-emitting diode transparent display panel as an example, the light-emitting diode transparent display panel includes a transparent substrate, a circuit structure disposed on the transparent substrate, and a plurality of light-emitting diodes electrically connected to the circuit structure. In order to further reduce the layout area of the opaque circuit structure and increase transparency, mini-ICs can be used to replace part of the functions of the circuit structure to drive the plurality of light-emitting diodes. Compared with the surrounding circuits, the area of the mini-IC is significantly larger. Although it is very difficult to reduce the area of the mini-IC, it is still necessary to further increase the aperture ratio and increase transparency.

### SUMMARY

The disclosure provides a display apparatus with a high aperture ratio.

A display apparatus of the disclosure includes a light-transmitting substrate, a pad group, a mini-IC, a first wire, and a first light-emitting element. The light-transmitting substrate has a pixel area. The pad group is disposed in the pixel area. The pad group includes a first pad, a second pad, and a third pad that are structurally separated from each other. The mini-IC is disposed in the pixel area and bonded to the pad group. The first wire is disposed in the pixel area and electrically connected to the first pad. The first pad and the second pad have first sides and second sides opposite to each other. The third pad is located on the first sides of the first pad and the second pad. The first wire is structurally separated from the second pad and the third pad. The first wire includes a winding segment. The winding segment of the first wire is disposed between the second pad and the third pad and bypasses the second pad from the first sides of the first pad and the second pad so as to extend toward the second sides of the first pad and the second pad.

### BRIEF DESCRIPTION OF THE DRAWINGS

FIG. 1 is a schematic top view of a display apparatus according to a first embodiment of the disclosure.

FIG. 2 is a schematic layout view of a pixel unit according to the first embodiment of the disclosure.

FIG. 3 is a schematic equivalent circuit view of a display apparatus according to the first embodiment of the disclosure.

FIG. 4 is a schematic top view of a display apparatus according to a Comparative Example.

FIG. 5 is a schematic layout view of a pixel unit according to a Comparative Example.

FIG. 6 is a schematic layout view of a pixel unit according to a second embodiment of the disclosure.

FIG. 7 is a schematic layout view of a pixel unit according to a third embodiment of the disclosure.

FIG. 8 is a schematic layout view of a pixel unit according to a fourth embodiment of the disclosure.

### DESCRIPTION OF THE EMBODIMENTS

Reference will now be made in detail to the present preferred embodiments of the disclosure, examples of which are illustrated in the accompanying drawings. Whenever possible, the same reference numbers are used in the drawings and description to refer to the same or like parts.

It should be understood that when an element such as a layer, film, region, or substrate is referred to as being “on” or “connected to” another element, it may be directly on or connected to another element, or intervening elements may also be present. In contrast, when an element is referred to as being “directly on” or “directly connected to” another element, no intervening elements are present. As used herein, “connected” may refer to physical connection and/or electrical connection. Furthermore, “electrical connection” or “coupling” may mean the presence of other elements between two elements.

The term “about,” “approximately,” or “substantially” as used herein is inclusive of the stated value and means within an acceptable range of deviation for the particular value as determined by people having ordinary skill in the art, considering the measurement in question and the error associated with measurement of the particular quantity (i.e., the limitations of the measurement system). For example, “about” may mean within one or more standard deviations, for example, within ±30%, ±20%, ±10%, ±5% of the stated value. Furthermore, a relatively acceptable range of deviation or standard deviation may be chosen for the terms “about,” “approximately,” or “substantially” as used herein based on optical properties, etching properties or other properties, instead of applying one standard deviation across all the properties.

Unless otherwise defined, all terms (including technical and scientific terms) used herein have the same meaning as commonly understood by people of ordinary skill in the art. It will be further understood that terms such as those defined in the commonly used dictionaries, should be interpreted as having a meaning that is consistent with their meaning in the context of the relevant art and the invention, and will not be interpreted in an idealized or overly formal sense unless expressly so defined herein.

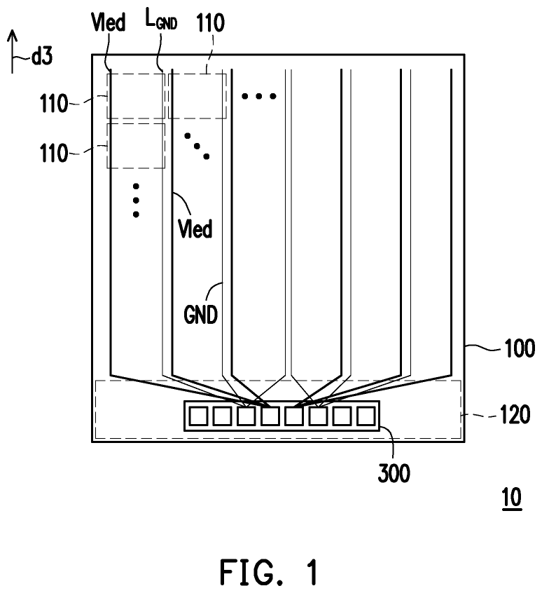

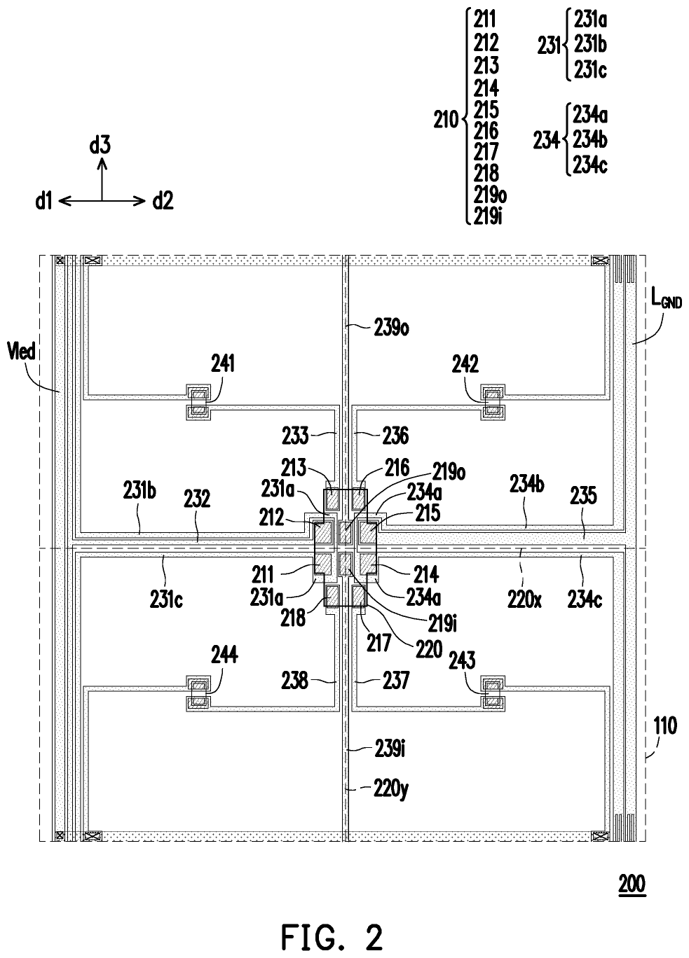

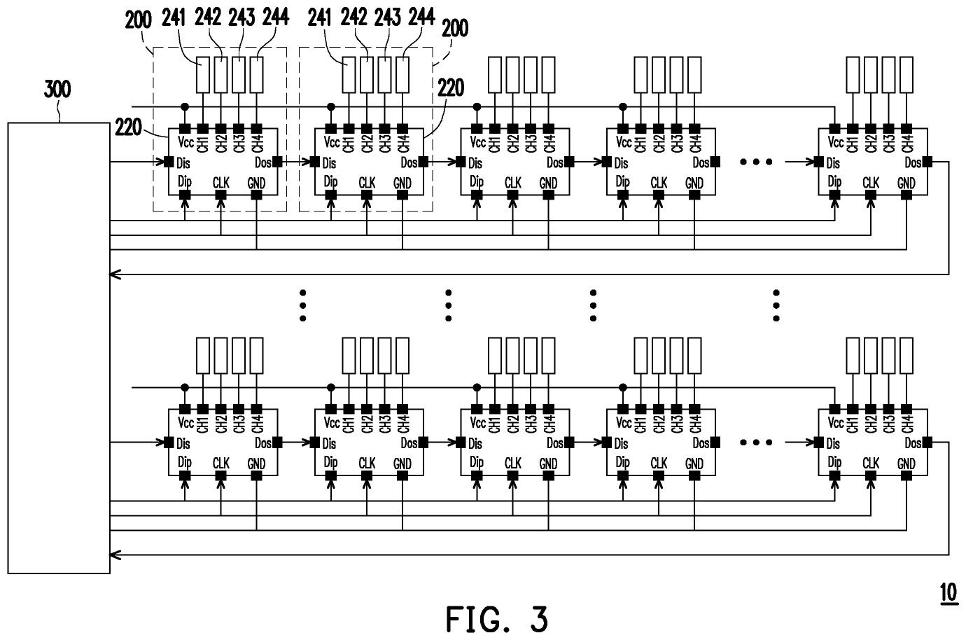

FIG. 1 is a schematic top view of a display apparatus according to a first embodiment of the disclosure. FIG. 1 schematically depicts a light-transmitting substrate 100, a wire Vled, a wire LGND, and a driving chip 300, while omitting other components. FIG. 2 is a schematic layout view of a pixel unit according to the first embodiment of the disclosure. A pixel unit 200 of FIG. 2 is located in a pixel area 110 of FIG. 1. FIG. 3 is a schematic equivalent circuit view of a display apparatus according to the first embodiment of the disclosure.

Referring to FIG. 1 and FIG. 2, a display apparatus 10 is a transparent display. The display apparatus 10 includes the light-transmitting substrate 100 and a plurality of pixel units 200. The light-transmitting substrate 100 has a plurality of pixel areas 110 arranged in an array. The plurality of pixel units 200 are respectively disposed in the plurality of pixel areas 110. For example, in the embodiment, the material of the light-transmitting substrate 100 can be glass, quartz, organic polymer, or other applicable materials, but the disclosure is not limited thereto.

Referring to FIG. 3, each pixel unit 200 includes a pad group 210, a mini-IC 220, a first wire 231, and a first light-emitting element 241, which are disposed in a corresponding pixel area 110. The pad group 210 includes a first pad 211, a second pad 212, and a third pad 213 that are structurally separated from each other. The mini-IC 220 is bonded to the pad group 210. The first wire 231 is electrically connected to the first pad 211. The first pad 211 and the second pad 212 have first sides (e.g., upper sides) and second sides (e.g., lower sides) opposite to each other. The third pad 213 is located on the first sides (e.g., the upper sides) of the first pad 211 and the second pad 212. The first wire 231 is structurally separated from the second pad 212 and the third pad 213. The first wire 231 includes a winding segment 231a. The winding segment 231a of the first wire 231 is disposed between the second pad 212 and the third pad 213 and bypasses the second pad 212 from the first sides (e.g., the upper sides) of the first pad 211 and the second pad 212 so as to extend toward the second sides (e.g., the lower sides) of the first pad 211 and the second pad 212. The first light-emitting element 241 is disposed in the pixel area 110 and electrically connected to the third pad 213.

In the embodiment, the display apparatus 10 further includes a second wire 232 electrically connected to the second pad 212 and extending toward a first direction d1 from the second pad 212. In the embodiment, the first wire 231 also includes a first transmission segment 231b and a second transmission segment 231c. The first transmission segment 231b and the second transmission segment 231c both extend toward the first direction d1. Two terminals of the winding segment 231a of the first wire 231 are respectively connected to the first transmission segment 231b and the second transmission segment 231c of the first wire 231, and the first transmission segment 231b and the second transmission segment 231c of the first wire 231 are respectively disposed on two opposite sides (e.g. upper and lower sides) of the second wire 232.

In the embodiment, the pad group 210 further includes a fourth pad 214, a fifth pad 215, and a sixth pad 216. The first pad 211, the second pad 212, the third pad 213, the fourth pad 214, the fifth pad 215, and the sixth pad 216 are structurally separated from each other. In the embodiment, the display apparatus 10 further includes a third wire 234 and a second light-emitting element 242. The third wire 234 is disposed in the pixel area 110 and electrically connected to the fourth pad 214. The fourth pad 214 and the fifth pad 215 has first sides (e.g., upper sides) and second sides (e.g., lower sides) opposite to each other. The sixth pad 216 is located on the first sides (e.g. the, upper sides) of the fourth pad 214 and the fifth pad 215. The third wire 234 is structurally separated from the fifth pad 215 and the sixth pad 216. The third wire 234 includes a winding segment 234a. The winding segment 234a of the third wire 234 is disposed between the fifth pad 215 and the sixth pad 216 and bypasses the fifth pad 215 from the first sides (e.g., the upper sides) of the fourth pad 214 and the fifth pad 215 so as to extend toward the second sides (e.g., the lower sides) of the fourth pad 214 and the fifth pad 215. The second light-emitting element 242 is disposed in the pixel area 110 and electrically connected to the sixth pad 216.

In the embodiment, the display apparatus 10 further includes a fourth wire 235 electrically connected to the fifth pad 215 and extending toward a second direction d2 from the fifth pad 215. The first direction d1 is opposite to the second direction d2. In the embodiment, the third wire 234 also includes a first transmission segment 234b and a second transmission segment 234c. The first transmission segment 234b and the second transmission segment 234c both extend toward the second direction d2. Two terminals of the winding segment 234a of the third wire 234 are respectively connected to the first transmission segment 234b and the second transmission segment 234c of the third wire 234, and the first transmission segment 234b and the second transmission segment 234c of the third wire 234 are respectively disposed on two opposite sides (e.g. upper and lower sides) of the fourth wire 235.

In the embodiment, the pad group 210 also includes a seventh pad 217 and an eighth pad 218. The first pad 211, the second pad 212, the third pad 213, the fourth pad 214, the fifth pad 215, the sixth pad 216, the seventh pad 217, and the eighth pad 218 are structurally separated from each other. In the embodiment, the display apparatus 10 further includes a third light-emitting element 243 and a fourth light-emitting element 244. The third light-emitting element 243 is disposed in the pixel area 110 and electrically connected to the seventh pad 217. The fourth light-emitting element 244 is disposed in the pixel area 110 and electrically connected to the eighth pad 218.

In the embodiment, the pad group 210 also includes a ninth pad 219o and a tenth pad 219i. The first pad 211, the second pad 212, the third pad 213, the fourth pad 214, the fifth pad 215, the sixth pad 216, the seventh pad 217, the eighth pad 218, the ninth pad 219o, and the tenth pad 219i are structurally separated from each other.

In the embodiment, the fifth pad 215, the ninth pad 219o, and the second pad 212 are sequentially arranged in a row along the first direction d1. The ninth pad 219o is located between the second pad 212 and the fifth pad 215. The fourth pad 214, the tenth pad 219i, and the first pad 211 are sequentially arranged in another row along the first direction d1, and the tenth pad 219i is located between the first pad 211 and the fourth pad 214. In short, in the embodiment, the first pad 211, the second pad 212, the fourth pad 214, the fifth pad 215, the ninth pad 219o, and the tenth pad 219i are arranged in a 3×2 array along the first direction d1 and a third direction d3. The first direction d1 intersects with the third direction d3.

In addition, in the embodiment, the third pad 213 electrically connected to the first light-emitting element 241 and the sixth pad 216 electrically connected to the second light-emitting element 242 are disposed outside the 3×2 array and located on one side (e.g., upper side) of the 3×2 array. The seventh pad 217 electrically connected to the third light-emitting element 243 and the eighth pad 218 electrically connected to the fourth light-emitting element 244 are disposed outside the 3×2 array and located on another side (e.g., lower side) of the 3×2 array.

Referring to FIG. 2 and FIG. 3, in the embodiment, the mini-IC 220 is bonded to the first pad 211, the second pad 212, the third pad 213, the fourth pad 214, the fifth pad 215, the sixth pad 216, the seventh pad 217, the eighth pad 218, the ninth pad 219o, and the tenth pad 219i of the pad group 210. Specifically, in the embodiment, the mini-IC 220 has a clock signal terminal CLK, a data input terminal Dip, a power supply terminal Vcc, a ground terminal GND, a series input terminal Dis, a series output terminal Dos, a first driving channel terminal CH1, a second driving channel terminal CH2, a third driving channel terminal CH3, and a fourth driving channel terminal CH4. The clock signal terminal CLK, the data input terminal Dip, the first driving channel terminal CH1, the power supply terminal Vcc, the ground terminal GND, the second driving channel terminal CH2, the third driving channel terminal CH3, the fourth driving channel terminal CH4, the series output terminal Dos, and the series input terminal Dis of the mini-IC 220 are respectively bonded to (or in other words, respectively electrically connected to) the first pad 211, the second pad 212, the third pad 213, the fourth pad 214, the fifth pad 215, the sixth pad 216, the seventh pad 217, the eighth pad 218, the ninth pad 219o, and the tenth pad 219i of the pad group 210. In the embodiment, the series output terminal Dos of the mini-IC 220 of the pixel unit 200 is electrically connected to the series input terminal Dis of the mini-IC 220 of the next adjacent pixel unit 200.

In the embodiment, the first light-emitting element 241, the second light-emitting element 242, the third light-emitting element 243, and the fourth light-emitting element 244 can be a plurality of mini LEDs, but the disclosure is not limited thereto.

In the embodiment, within a pixel area 110, the first wire 231, the second wire 232, a wire 233, the third wire 234, the fourth wire 235, a wire 236, a wire 237, a wire 238, a wire 239o, and a wire 239i respectively electrically connected to the first pad 211, the second pad 212, the third pad 213, the fourth pad 214, the fifth pad 215, the sixth pad 216, the seventh pad 217, the eighth pad 218, the ninth pad 219o, and the tenth pad 219i may belong to conductive layers of the same film layer (e.g., a second metal layer). The first wire 231, the second wire 232, the wire 233, the third wire 234, the fourth wire 235, the wire 236, the wire 237, the wire 238, the wire 239o, and the wire 239i do not intersect and there is no overlapping region.

Referring to FIG. 2, in the embodiment, the pixel unit 200 may further include the wire Vled and the wire LGND. The wire Vled extends in the third direction d3 and is electrically connected to the first light-emitting element 241, the second light-emitting element 242, the third light-emitting element 243, and the fourth light-emitting element 244. The wire LGND and the fourth wire 235 intersect and are directly connected. Referring to FIG. 1 and FIG. 2, a plurality of segments of wires Vled of the plurality of pixel units 200 arranged in the same column in the third direction d3 can be connected in series into the same wire, and then electrically connected to the peripheral driving chip 300; a plurality of segments of wires LGND of the plurality of pixel units 200 arranged in the same column in the third direction d3 can be connected in series to form another wire, and then electrically connected to the peripheral driving chip 300.

It is worth mentioning that through the design of the first wire 231 having the winding segment 231a, the first wire 231 does not need to intersect with other wires of different film layers at least within the orthographic projection area of the mini-IC 220. Instead, the peripheral driving chip 300 disposed in a peripheral area 120 respectively provides signals to the mini-ICs 220 of the plurality of pixel units 200. Thereby, a resistance-capacitance loading (RC loading) of each pixel unit 200 can be reduced, which helps to improve the electrical properties of the display apparatus 10. In addition, the first wire 231, the second wire 232, the wire 233, the third wire 234, the fourth wire 235, the wire 236, the wire 237, the wire 238, the wire 239o, and the wire 239i of the pixel unit 200 are generally concentrated toward the cross-shaped area overlapping two axes 220x and 220y of the mini-IC 220. Thereby, the aperture ratio of the pixel unit 200 can also be increased while the RC loading is reduced, thereby improving the transparency effect of the display apparatus 10.

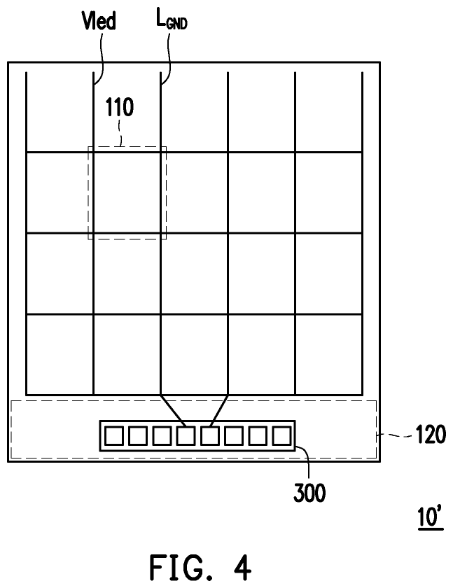

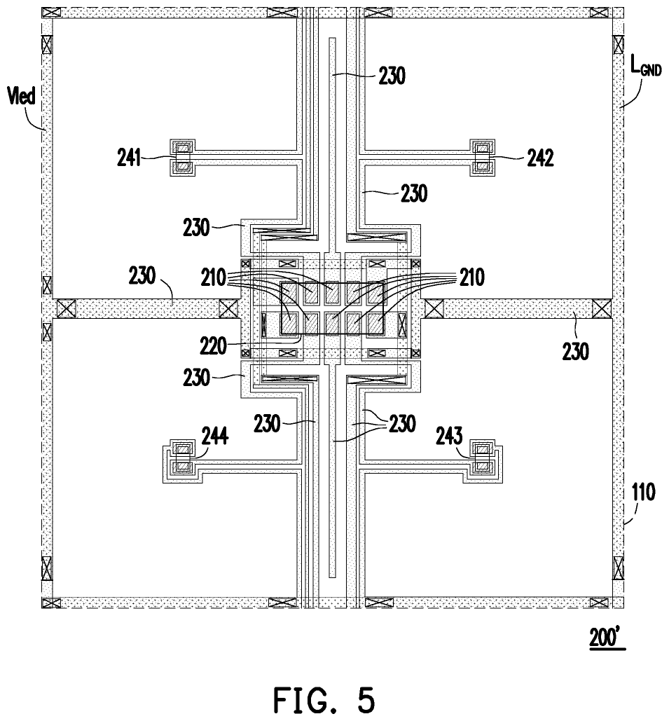

FIG. 4 is a schematic top view of a display apparatus according to a Comparative Example. FIG. 4 schematically depicts the light-transmitting substrate 100, the wire Vled, the wire LGND, and the driving chip 300, while omitting other components. FIG. 5 is a schematic layout view of a pixel unit according to a Comparative Example. A pixel unit 200′ of FIG. 5 is located in the pixel area 110 of FIG. 4.

A display apparatus 10′ of the Comparative Example of FIG. 4 and FIG. 5 is similar to the display apparatus 10 of the first embodiment of FIG. 1 and FIG. 2, so the same or similar components are denoted by the same or similar reference numbers. The difference between the two is that in the Comparative Example of FIG. 4 and FIG. 5, a plurality of wires 230 electrically connected to the pad group 210 include a plurality of parts belonging to different first metal layers and second metal layers, the plurality of wires 230 have a plurality of overlapping regions, and the pixel unit 200′ of the Comparative Example has a larger RC loading.

Table 1 shows the overlapping area of the first metal layer and the second metal layer in the pixel area 110, the overlapping area of the first metal layer and the second metal layer in the peripheral area 120, and the sum of the overlapping area of the first metal layer and the second metal layer in the plurality of pixel areas 110 and the overlapping area of the first metal layer and the second metal layer in the peripheral area 120 of the display apparatus 10 and the display apparatus 10′ of the Comparative Example and the first embodiment.

TABLE 1

| | Display apparatus 10′ | | Display apparatus 10 | |
|---|---|---|---|---|
| | of Comparative Example | | of first embodiment | |
| In the pixel area 110, the overlapping area | 161000 | μm² | 20000 | μm² |
| of the first metal layer and the second metal | | | | |
| layer | | | | |
| In the peripheral area 120, the overlapping | 451250 | μm² | 1106500 | μm² |
| area of the first metal layer and the second | | | | |
| metal layer | | | | |
| The sum of the overlapping area of the first | 22347250 | μm² | 3826500 | μm² |
| metal layer and the second metal layer in the | | | | |
| plurality of pixel areas 110 and the | | | | |
| overlapping area of the first metal layer and | | | | |
| the second metal layer in the peripheral area | | | | |
| 120 | | | | |

It can be confirmed from the data in Table 1 that compared with the Comparative Example, the first embodiment can indeed reduce the overlapping area of the first metal layer and the second metal layer in the pixel area 110. In addition, although the overlapping area of the first metal layer and the second metal layer in the peripheral area 120 of the display apparatus 10 of the first embodiment is larger than the overlapping area of the first metal layer and the second metal layer in the peripheral area 120 of the display apparatus 10′ of the Comparative Example, the sum of the overlapping areas of the first metal layer and the second metal layer in the plurality of pixel areas 110 and the peripheral area 120 of the display apparatus 10 of the first embodiment is still smaller than the sum of the overlapping areas of the first metal layer and the second metal layer in the plurality of pixel areas 110 and the peripheral area 120 of the display apparatus 10′ of the Comparative Example. It can be verified from this that the RC loading of the display apparatus 10 of the first embodiment is smaller and has better electrical properties than the RC loading of the display apparatus 10′ of the Comparative Example.

It must be noted here that the following embodiments adopt the reference numbers and partial contents of the foregoing embodiments, wherein the same reference numbers are used to indicate the same or similar elements, and the description of the same technical content is omitted. For the description of the omitted parts, reference may be made to the foregoing embodiments, and the same content will not be repeated in the following embodiments.

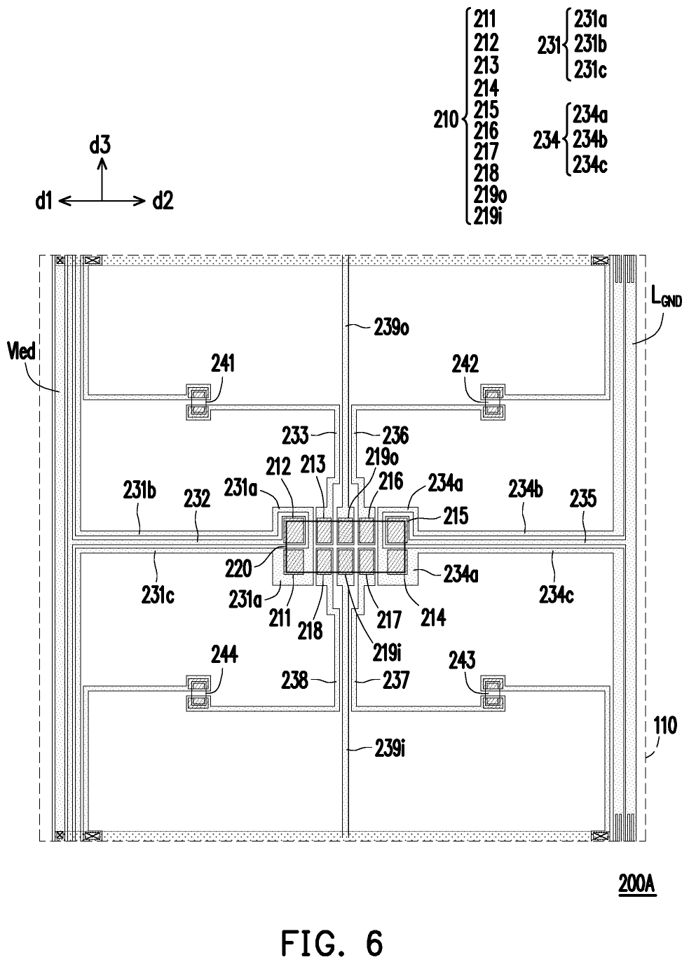

FIG. 6 is a schematic layout view of a pixel unit according to a second embodiment of the disclosure. A pixel unit 200A of FIG. 6 is similar to the pixel unit 200 of FIG. 2. The difference between the two is that the arrangement of the first pad 211, the second pad 212, the third pad 213, the fourth pad 214, the fifth pad 215, the sixth pad 216, the seventh pad 217, the eighth pad 218, the ninth pad 219o, and the tenth pad 219i of the pad group 210 is different.

Please refer to FIG. 6. Specifically, in the embodiment, the fifth pad 215, the sixth pad 216, the third pad 213, and the second pad 212 are sequentially arranged in a row along the first direction d1, and the fourth pad 214, the seventh pad 217, the tenth pad 219i, the eighth pad 218, and the first pad 211 are sequentially arranged in another row along the first direction d1. In short, in the embodiment, the first pad 211, the second pad 212, the third pad 213, the fourth pad 214, the fifth pad 215, the sixth pad 216, the seventh pad 217, the eighth pad 218, the ninth pad 219o, and the tenth pad 219i of the pad group 210 may be arranged in a 5×2 array.

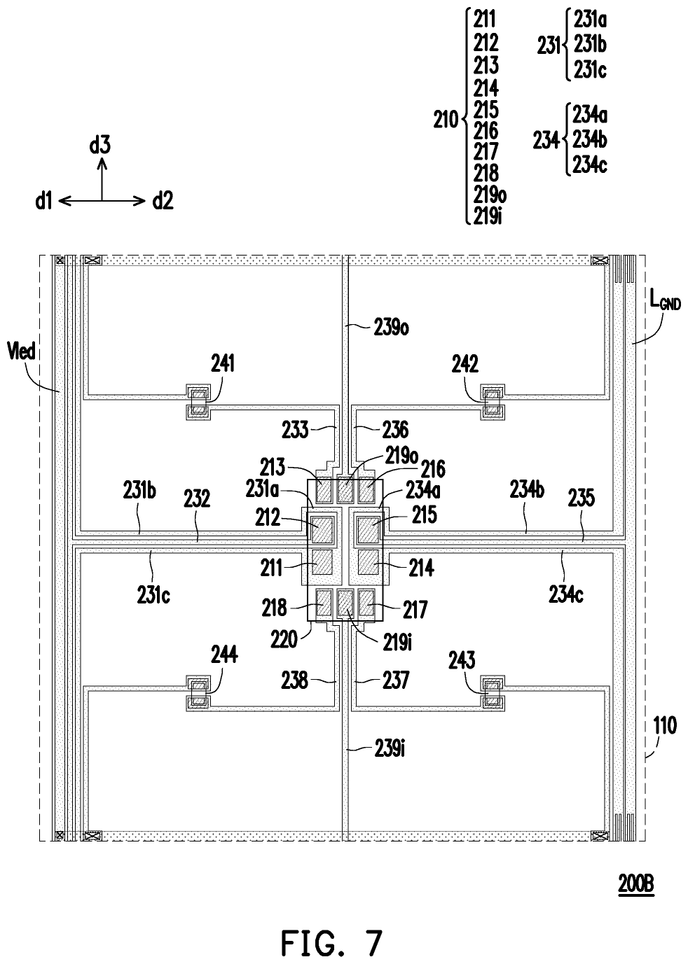

FIG. 7 is a schematic layout view of a pixel unit according to a third embodiment of the disclosure. A pixel unit 200B of FIG. 7 is similar to the pixel unit 200 of FIG. 2. The difference between the two is that the arrangement of the first pad 211, the second pad 212, the third pad 213, the fourth pad 214, the fifth pad 215, the sixth pad 216, the seventh pad 217, the eighth pad 218, the ninth pad 219o, and the tenth pad 219i of the pad group 210 is different.

Please refer to FIG. 7. Specifically, in the embodiment, the first pad 211, the second pad 212, the fourth pad 214, and the fifth pad 215 are arranged in a 2×2 array along the first direction d1 and the third direction d3. The third pad 213 electrically connected to the first light-emitting element 241 and the sixth pad 216 electrically connected to the second light-emitting element 242 are disposed outside the 2×2 array and located on one side (e.g., upper side) of the 2×2 array. The seventh pad 217 electrically connected to the third light-emitting element 243 and the eighth pad 218 electrically connected to the fourth light-emitting element 244 are disposed outside the 2×2 array and located on another side (e.g., lower side) of the 2×2 array.

In addition, in the embodiment, the ninth pad 219o is disposed outside the 2×2 array and located on the side (e.g., the upper side) of the 2×2 array, and the ninth pad 219o is located between the third pad 213 and the sixth pad 216; the tenth pad 219i is disposed outside the 2×2 array and located on the another side (e.g., the lower side) of the 2×2 array, and the tenth pad 219i is located between the seventh pad 217 and the eighth pad 218.

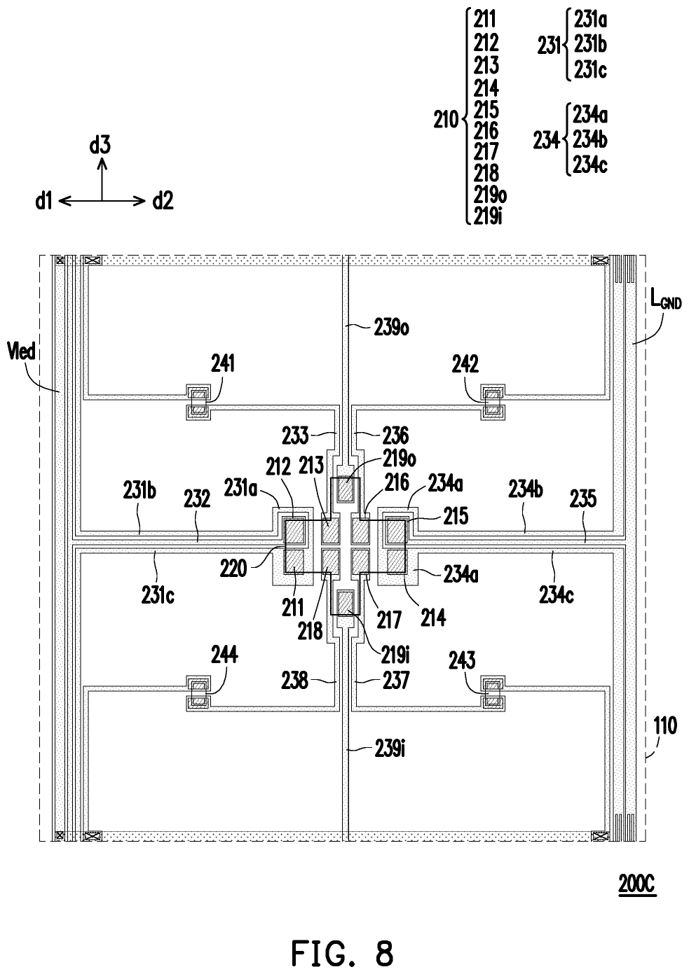

FIG. 8 is a schematic layout view of a pixel unit according to a fourth embodiment of the disclosure. A pixel unit 200C of FIG. 8 is similar to the pixel unit 200 of FIG. 2. The difference between the two is that the arrangement of the first pad 211, the second pad 212, the third pad 213, the fourth pad 214, the fifth pad 215, the sixth pad 216, the seventh pad 217, the eighth pad 218, the ninth pad 219o, and the tenth pad 219i of the pad group 210 is different.

Please refer to FIG. 8. Specifically, in the embodiment, the first pad 211, the second pad 212, the third pad 213, the fourth pad 214, the fifth pad 215, and the sixth pad 216, the seventh pad 217, and the eighth pad 218 are arranged in a 4×2 array along the first direction d1 and the third direction d3, and the ninth pad 219o and the tenth pad 219i are disposed outside the 4×2 array and respectively located on two opposite sides of the 4×2 array (e.g., upper and lower sides).

Table 2 lists the area of the pixel area 110 of the pixel units 200′, 200, 200A, 200B, and 200C and the aperture ratios of the pixel units 200′, 200, 200A, 200B, and 200C of the Comparative Example and the first, second, third, and fourth embodiments. As shown in Table 2, the aperture ratios of the pixel units 200, 200A, 200B, and 200C of various embodiments of the disclosure are all higher than the aperture ratio of the pixel unit 200′ of the Comparative Example. The display apparatus using the pixel units 200, 200A, 200B, and 200C of various embodiments of the disclosure has a favorable transparent display effect.

TABLE 2

| | Pixel unit | | | | |
|---|---|---|---|---|---|
| | 200′ of | Pixel unit | Pixel unit | Pixel unit | Pixel unit |
| | Comparative | 200 of the first | 200A of second | 200B of third | 200C of fourth |
| | Example | embodiment | embodiment | embodiment | embodiment |
| Area of pixel area | 530400 μm² | 592344 μm² | 530400 μm² | 788824 μm² | 595642 μm² |
| Aperture ratio of | 71.4% | 78.0% | 77.5% | 77.4% | 77.8% |
| pixel unit | | | | | |

What is claimed is:

1. A display apparatus, comprising:
a light-transmitting substrate, having a pixel area;
a pad group, disposed in the pixel area, wherein the pad group comprises a first pad, a second pad, and a third pad that are structurally separated from each other;
a mini-IC, disposed in the pixel area, and bonded to the pad group;
a first wire, disposed in the pixel area, and electrically connected to the first pad, wherein the first pad and the second pad have first sides and second sides opposite to each other, the third pad is located on the first sides of the first pad and the second pad, the first wire is structurally separated from the second pad and the third pad, the first wire comprises a winding segment, and the winding segment of the first wire is disposed between the second pad and the third pad and bypasses the second pad from the first sides of the first pad and the second pad so as to extend toward the second sides of the first pad and the second pad; and
a first light-emitting element, disposed in the pixel area, and electrically connected to the third pad.

2. The display apparatus according to claim 1, further comprising:
a second wire, electrically connected to the second pad, and extending toward a first direction from the second pad, wherein the first wire further comprises:
a first transmission segment, extending toward the first direction; and
a second transmission segment, extending toward the first direction, wherein two terminals of the winding segment of the first wire are respectively connected to the first transmission segment and the second transmission segment of the first wire, and the first transmission segment and the second transmission segment of the first wire are respectively disposed on two opposite sides of the second wire.

3. The display apparatus according to claim 2, wherein the pad group further comprises a fourth pad, a fifth pad, and a sixth pad, the first pad, the second pad, the third pad, the fourth pad, the fifth pad, and the sixth pad are structurally separated from each other, and the display apparatus further comprises:
a third wire, disposed in the pixel area, and electrically connected to the fourth pad, wherein the fourth pad and the fifth pad have first sides and second sides opposite to each other, the sixth pad is located on the first sides of the fourth pad and the fifth pad, the third wire is structurally separated from the fifth pad and the sixth pad, the third wire comprises a winding segment, and the winding segment of the third wire is disposed between the fifth pad and the sixth pad and bypasses the fifth pad from the first sides of the fourth pad and the fifth pad so as to extend toward the second sides of the fourth pad and the fifth pad; and
a second light-emitting element, disposed in the pixel area, and electrically connected to the sixth pad.

4. The display apparatus according to claim 3, further comprising:
a fourth wire, electrically connected to the fifth pad, and extending toward a second direction from the fifth pad, wherein the first direction is opposite to the second direction, and the third wire further comprises:
a first transmission segment, extending toward the second direction; and
a second transmission segment, extending toward the second direction, wherein two terminals of the winding segment of the third wire are respectively connected to the first transmission segment and the second transmission segment of the third wire, and the first transmission segment and the second transmission segment of the third wire are respectively disposed on two opposite sides of the fourth wire.

5. The display apparatus according to claim 3, wherein the fifth pad, the sixth pad, the third pad, and the second pad are sequentially arranged in a row along the first direction, and the fourth pad and the first pad are sequentially arranged in another row along the first direction.

6. The display apparatus according to claim 5, wherein the pad group further comprises a seventh pad and an eighth pad, the first pad, the second pad, the third pad, the fourth pad, the fifth pad, the sixth pad, the seventh pad, and the eighth pad are structurally separated from each other, and the display apparatus further comprises:
a third light-emitting element, disposed in the pixel area, and electrically connected to the seventh pad; and
a fourth light-emitting element, disposed in the pixel area, and electrically connected to the eighth pad;
wherein the fourth pad, the seventh pad, the eighth pad, and the first pad are sequentially arranged in the another row along the first direction.

7. The display apparatus according to claim 6, wherein the pad group further comprises a ninth pad and a tenth pad, the first pad, the second pad, the third pad, the fourth pad, the fifth pad, the sixth pad, the seventh pad, the eighth pad, the ninth pad, and the tenth pad are structurally separated from each other, the fifth pad, the sixth pad, the ninth pad, the third pad, and the second pad are sequentially arranged in the row along the first direction, and the fourth pad, the seventh pad, the tenth pad, the eighth pad, and the first pad are sequentially arranged in the another row along the first direction.

8. The display apparatus according to claim 6, wherein the pad group further comprises a ninth pad and a tenth pad, the first pad, the second pad, the third pad, the fourth pad, the fifth pad, the sixth pad, the seventh pad, and the eighth pad are arranged in an array along the first direction and a third direction, and the ninth pad and the tenth pad are disposed outside the array and respectively located on two opposite sides of the array.

9. The display apparatus according to claim 3, wherein the pad group further comprises a seventh pad and an eighth pad, the first pad, the second pad, the third pad, the fourth pad, the fifth pad, the sixth pad, the seventh pad, and the eighth pad are structurally separated from each other, and the display apparatus further comprises:
a third light-emitting element, disposed in the pixel area, and electrically connected to the seventh pad; and
a fourth light-emitting element, disposed in the pixel area, and electrically connected to the eighth pad;
wherein a third direction intersects with the first direction, the first pad, the second pad, the fourth pad, and the fifth pad are arranged in an array along the first direction and the third direction, the third pad electrically connected to the first light-emitting element and the sixth pad electrically connected to the second light-emitting element are disposed outside the array and located on one side of the array, and the seventh pad electrically connected to the third light-emitting element and the eighth pad electrically connected to the fourth light-emitting element are disposed outside the array and located on another side of the array.

10. The display apparatus according to claim 9, wherein the pad group further comprises a ninth pad and a tenth pad, the first pad, the second pad, the third pad, the fourth pad, the fifth pad, the sixth pad, the seventh pad, the eighth pad, the ninth pad, and the tenth pad are structurally separated from each other, the first pad, the second pad, the fourth pad, and the fifth pad, the ninth pad, and the tenth pad are disposed in the array along the first direction and the third direction, the ninth pad is located between the second pad and the fifth pad, and the tenth pad is located between the first pad and the fourth pad.

11. The display apparatus according to claim 9, wherein the pad group further comprises a ninth pad and a tenth pad, the first pad, the second pad, the third pad, the fourth pad, the fifth pad, the sixth pad, the seventh pad, the eighth pad, the ninth pad, and the tenth pad are structurally separated from each other, the third pad, the ninth pad, and the sixth pad are disposed outside the array and located on the side of the array, the ninth pad is located between the third pad and sixth pad, the seventh pad, the tenth pad, and the eighth pad are disposed outside the array and located on the another side of the array, and the tenth pad is located between the seventh pad and the eighth pad.
